(19) United States
(12) Patent Application Publication
(10) Pub. No.: US 2025/0118685 A1
(43) Pub. Date: Apr. 10, 2025

(54) SEMICONDUCTOR DEVICE AND METHOD OF MANUFACTURING THE SAME

(71) Applicant: Renesas Electronics Corporation, Tokyo (JP)

(72) Inventors: Takashi MORIYAMA, Tokyo (JP); Tohru KAWAI, Tokyo (JP)

(21) Appl. No.: 18/904,186

(22) Filed: Oct. 2, 2024

(30) Foreign Application Priority Data
Oct. 5, 2023 (JP) 2023-173746

(51) Int. Cl. H01L 23/58; H01L 21/78; H01L 23/00; H01L 23/31

(52) U.S. Cl. CPC H01L 23/585; H01L 21/78; H01L 23/3171; H01L 23/562

(57) ABSTRACT

A semiconductor device includes a semiconductor substrate, a multilayer wiring structure formed on the semiconductor substrate, a guard ring formed so as to surround a circuit formation region and penetrate the multilayer wiring structure, and a pad formed on the multilayer wiring structure. A protective film is formed so as to cover the multilayer wiring structure, the guard ring, and the pad. A trench is formed so as to penetrate the protective film and reach an inside of the multilayer wiring structure. The trench is formed so as to surround the guard ring. The guard ring includes a wiring formed on the multilayer wiring structure. The trench is spaced apart from and adjacent to the wiring. A bottom surface of the trench is inclined so as to be continuously deepened in a direction from the circuit formation region toward a peripheral region surrounding the circuit formation region.

### CROSS-REFERENCE TO RELATED APPLICATIONS

The disclosure of Japanese Patent Application No. 2023-173746 filed on Oct. 5, 2023 including the specification, drawings and abstract is incorporated herein by reference in its entirety.

### BACKGROUND

The present invention relates to a semiconductor device and a method of manufacturing the same, and can be preferably used, for example, for a semiconductor device having a guard ring and a method of manufacturing the same.

In a semiconductor device, a protection structure called a guard ring or a seal ring for preventing entry of moisture is formed.

There are disclosed techniques listed below.
[Patent Document 1] Japanese Unexamined Patent Application Publication No. 2004-79596

Patent Document 1 describes a technique related to a semiconductor device having a seal ring. Patent Document 1 describes that an opening 123 is formed in a passivation film 120 so as to surround an outer side of a seal ring 110.

### SUMMARY

In a semiconductor device having a guard ring, it is desired to improve reliability.

Other problems and novel features will become apparent from the description of the present specification and the accompanying drawings.

According to an embodiment, a semiconductor device includes a semiconductor substrate, a multilayer wiring structure formed on the semiconductor substrate, a guard ring formed so as to surround a circuit formation region and so as to penetrate the multilayer wiring structure, and a pad formed on the multilayer wiring structure. The semiconductor device further includes a protective film formed so as to cover the multilayer wiring structure, the guard ring, and the pad. The semiconductor device further includes a trench formed so as to surround the guard ring, and formed so as to penetrate the protective film and reach an inside of the multilayer wiring structure. The guard ring includes first wiring formed on the multilayer wiring structure so as to surround the circuit formation region. A bottom surface of the trench is inclined so as to be continuously deepened in a direction from the circuit formation region toward a peripheral region surrounding the circuit formation region.

According to an embodiment, the reliability of a semiconductor device can be improved.

### BRIEF DESCRIPTION OF THE DRAWINGS

FIG. 1 is an overall plan view of a semiconductor device of a first embodiment.

FIG. 2 is a cross-sectional view of a main part of the semiconductor device of the first embodiment.

FIG. 3 is a cross-sectional view of the main part of the semiconductor device of the first embodiment.

FIG. 4 is a plan view illustrating a semiconductor substrate used in a manufacturing process of the semiconductor device of the first embodiment.

FIG. 5 is a cross-sectional view of a main part in the manufacturing process of the semiconductor device of the first embodiment.

FIG. 6 is a cross-sectional view of the main part in the manufacturing process of the semiconductor device, following FIG. 5.

FIG. 7 is a cross-sectional view of the main part in the manufacturing process of the semiconductor device, following FIG. 6.

FIG. 8 is a cross-sectional view of the main part in the manufacturing process of the semiconductor device, following FIG. 7.

FIG. 9 is a cross-sectional view of the main part in the manufacturing process of the semiconductor device, following FIG. 8.

FIG. 10 is a cross-sectional view of the main part in the manufacturing process of the semiconductor device following FIG. 9.

FIG. 11 is a cross-sectional view of the main part in the manufacturing process of the semiconductor device, following FIG. 10.

FIG. 12 is a cross-sectional view of a main part of a semiconductor device of a study example.

FIG. 13 is a cross-sectional view of the main part in the manufacturing process of the semiconductor device of the first embodiment.

FIG. 14 is a cross-sectional view of the main part in the manufacturing process of the semiconductor device, following FIG. 13.

FIG. 15 is a cross-sectional view of the main part in the manufacturing process of the semiconductor device, following FIG. 14.

FIG. 16 is a cross-sectional view of the main part in the manufacturing process of the semiconductor device, following FIG. 15.

FIG. 17 is a cross-sectional view of the main part in the manufacturing process of the semiconductor device, following FIG. 16.

FIG. 18 is a cross-sectional view of a main part of a semiconductor device of a modification of the first embodiment.

FIG. 19 is a cross-sectional view of a main part of a semiconductor device of a second embodiment.

FIG. 20 is a cross-sectional view of a main part of a semiconductor device of a modification of the second embodiment.

FIG. 21 is a cross-sectional view of the main part in the manufacturing process of the semiconductor device of the second embodiment.

FIG. 22 is a cross-sectional view of the main part in the manufacturing process of the semiconductor device, following FIG. 21.

FIG. 23 is a cross-sectional view of the main part in the manufacturing process of the semiconductor device, following FIG. 22.

FIG. 24 is a cross-sectional view of the main part in the manufacturing process of the semiconductor device, following FIG. 23.

FIG. 25 is a cross-sectional view of the main part in the manufacturing process of the semiconductor device, following FIG. 24.

FIG. 26 is a cross-sectional view of the main part in the manufacturing process of the semiconductor device, following FIG. 25.

FIG. 27 is a cross-sectional view of a main part of a semiconductor device of a third embodiment.

FIG. 28 is a cross-sectional view of a main part of a semiconductor device of a modification of the third embodiment.

FIG. 29 is a cross-sectional view of the main part in the manufacturing process of the semiconductor device of the third embodiment.

FIG. 30 is a cross-sectional view of the main part in the manufacturing process of the semiconductor device, following FIG. 29.

FIG. 31 is a cross-sectional view of the main part in the manufacturing process of the semiconductor device, following FIG. 30.

### DETAILED DESCRIPTION

In the following embodiments, when necessary for convenience, a description divided into a plurality of sections or embodiments will be given, but unless otherwise specified, the sections or embodiments are not irrelevant to each other, and one is in a relationship of some or all modifications, details, supplementary description, and the like of another. In addition, in the following embodiments, when referring to the number of elements and the like (including number, numerical value, amount, range, and the like), the number is not limited to a specific number unless otherwise specified or clearly limited to the specific number in principle, and the number may be equal to or more than the specific number or may be equal to or less than the specific number. Furthermore, in the following embodiments, it goes without saying that the components (including element steps and the like) are not necessarily essential unless otherwise specified or considered to be obviously essential in principle. Similarly, in the following embodiments, when referring to the shape, positional relationship, and the like of the components and the like, it is assumed to include those substantially approximate or similar to the shape and the like unless otherwise specified or unless clearly considered otherwise in principle. The same applies to the above numerical value and range.

Hereinafter, embodiments will be described in detail with reference to the drawings. Note that, in all the drawings for describing the embodiments, members having the same functions are denoted by the same reference numerals, and repeated description thereof will be omitted. Further, in the following embodiments, descriptions of the same or similar parts will not be repeated in principle unless particularly necessary.

Further, in the drawings used in the embodiments, hatching may be omitted to make the drawings easy to see even in a cross-sectional view. In addition, even in a plan view, hatching may be applied to make the drawing easy to see.

### First Embodiment

### <Structure of Semiconductor Device>

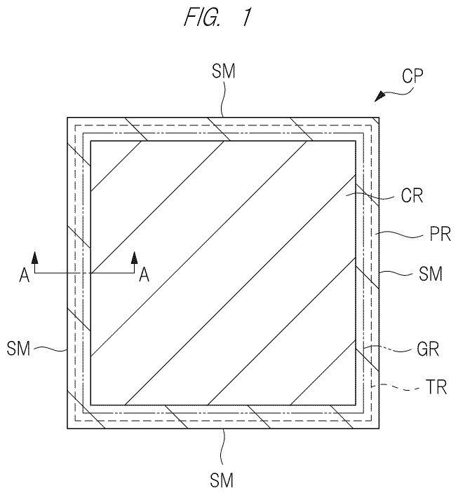

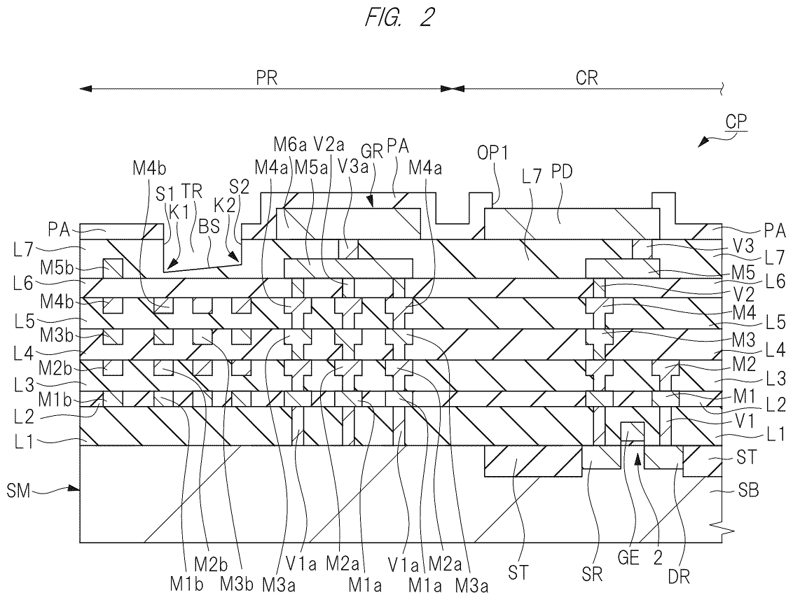

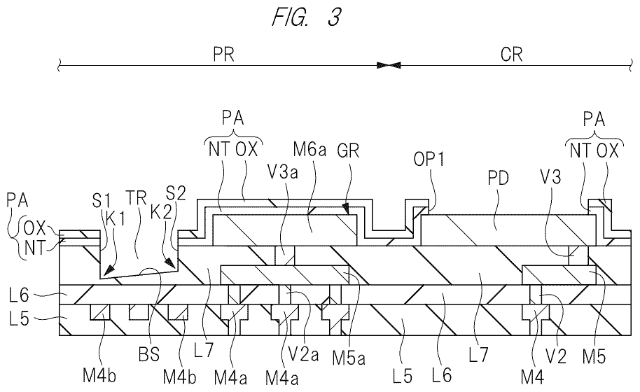

A semiconductor device according to the present embodiment will be described with reference to the drawings. FIG. 1 is an overall plan view of a semiconductor device CP according to the present embodiment. FIG. 2 is a cross-sectional view of a main part of the semiconductor device CP according to the present embodiment. A cross-sectional view taken along line A-A in FIG. 1 corresponds to FIG. 2. In FIG. 1, the position of a guard ring GR is indicated by a two-dot chain line, and the position of a trench TR is indicated by a broken line. Further, in FIG. 1, a circuit formation region CR and a peripheral region PR are hatched. In FIG. 1, the hatching direction of the circuit formation region CR and the hatching direction of the peripheral region PR are different from each other. Further, in FIG. 2, a left end of the semiconductor device CP is a side surface SM of the semiconductor device CP. The side surface SM of the semiconductor device CP corresponds to a cut surface when the semiconductor wafer is cut along a scribe region. Further, in FIG. 2, a right end of the semiconductor device CP corresponds to a position inside the semiconductor device CP, not a side surface of the semiconductor device CP. FIG. 3 is a cross-sectional view illustrating a part of FIG. 2, and illustrates a structure above an interlayer insulating film L4 in FIG. 2.

As illustrated in FIG. 1, the semiconductor device (semiconductor chip) CP includes the circuit formation region CR, the peripheral region PR located on an outer periphery (periphery) of the circuit formation region CR, the guard ring GR formed in the peripheral region PR, and the trench TR formed in the peripheral region PR. The guard ring may also be referred to as a seal ring.

Various circuits are formed in the circuit formation region CR. In plan view, the peripheral region PR surrounds the circuit formation region CR. That is, in plan view, the peripheral region PR corresponds to a region between the side surface SM of the semiconductor device CP and the circuit formation region CR.

Note that the term “plan view” refers to a case of being viewed in a plane parallel to a main surface of a semiconductor substrate SB constituting the semiconductor device CP.

In plan view, the guard ring GR is formed in the peripheral region PR of the semiconductor device CP so as to surround the circuit formation region CR. That is, the guard ring GR is formed along the outer periphery of the semiconductor device CP.

In plan view, the trench TR is formed in the peripheral region PR of the semiconductor device CP so as to surround the guard ring GR. The trench TR and the guard ring GR run in parallel along the outer periphery of the semiconductor device CP, and the trench TR is located between the side surface SM of the semiconductor device CP and the guard ring GR in plan view.

Next, a specific configuration of the semiconductor device CP of the present embodiment will be described with reference to FIGS. 2 and 3.

As illustrated in FIG. 2, the semiconductor device CP of the present embodiment includes the semiconductor substrate SB made of single crystal silicon or the like, a multilayer wiring structure formed on the semiconductor substrate SB, a pad PD formed on the multilayer wiring structure, a wiring M6a formed on the multilayer wiring structure, and a protective film PA formed on the multilayer wiring structure. The protective film PA is formed so as to cover the multilayer wiring structure, the pad PD, and the guard ring GR. Here, the multilayer wiring structure corresponds to a wiring structure including a plurality of wiring layers.

As illustrated in FIG. 2, a semiconductor element such as a metal insulator semiconductor field effect transistor (MISFET) 2 is formed on the semiconductor substrate SB. The main surface of the semiconductor substrate SB has the circuit formation region CR and the peripheral region PR described above, and the semiconductor element such as the MISFET 2 is formed in the circuit formation region CR.

For example, an element isolation region ST is formed on the semiconductor substrate SB by a shallow trench isolation (STI) method or the like, and the MISFET 2 is formed in an active region of the semiconductor substrate SB defined by the element isolation region ST. The MISFET 2 includes a source region SR and a drain region DR formed on the semiconductor substrate SB, and a gate electrode GE formed on the semiconductor substrate SB via a gate insulating film.

In addition, here, the MISFET is described as an example of the semiconductor element, but a capacitance element, a resistance element, a memory element, a transistor having another configuration, or the like can also be formed.

The multilayer wiring structure (multilayer wiring layer) including a plurality of interlayer insulating films and a plurality of wiring layers is formed on the main surface of the semiconductor substrate SB.

That is, a plurality of interlayer insulating films L1, L2, L3, L4, L5, 16, and L7 is stacked on the semiconductor substrate SB, and wirings M1, M1a, M1b, M2, M2a, M2b, M3, M3a, M3b, M4, M4a, M4b, M5, M5a, and M5b are formed in the plurality of interlayer insulating films L1, L2, L3, L4, 15, 16, and L7.

Specifically, the interlayer insulating film L2 is formed on the interlayer insulating film L1, the interlayer insulating film L3 is formed on the interlayer insulating film L2, the interlayer insulating film L4 is formed on the interlayer insulating film L3, the interlayer insulating film L5 is formed on the interlayer insulating film L4, the interlayer insulating film L6 is formed on the interlayer insulating film L5, and the interlayer insulating film L7 is formed on the interlayer insulating film L6. The interlayer insulating film L7 is an uppermost interlayer insulating film among the plurality of interlayer insulating films of the multilayer wiring structure. Note that each of the interlayer insulating films L1, L2, L3, L4, L5, L6, and L7 may be a single-layer insulating film or a stacked insulating film including a plurality of insulating films.

The wirings M1, M1a, and M1b are wirings of a first wiring layer. The first wiring layer is a lowermost wiring layer among the plurality of wiring layers included in the multilayer wiring structure. The wirings M2, M2a, and M2b are wirings of a second wiring layer which is a wiring layer one layer higher than the first wiring layer. The wirings M3, M3a, and M3b are wirings of a third wiring layer which is a wiring layer one layer higher than the second wiring layer. The wirings M4, M4a, and M4b are wirings of a fourth wiring layer which is a wiring layer one layer higher than the third wiring layer. The wirings M5, M5a, and M5b are wirings of a fifth wiring layer which is a wiring layer one layer higher than the fourth wiring layer. The fifth wiring layer is an uppermost wiring layer among the plurality of wiring layers included in the multilayer wiring structure. Note that the number of wiring layers included in the multilayer wiring structure is not limited to five.

A via portion V1 is embedded in the interlayer insulating film L1. In the case of FIG. 2, each of the wirings M1, M1a, M1b, M2, M2a, M2b, M3, M3a, M3b, M4, M4a, and M4b is a damascene wiring. Therefore, the wirings M1, M1a, and M1b are embedded in the interlayer insulating film L2, the wirings M2, M2a, and M2b are embedded in the interlayer insulating film L3, the wirings M3, M3a, and M3b are embedded in the interlayer insulating film L4, and the wirings M4, M4a, and M4b are embedded in the interlayer insulating film L5. In addition, the wirings M1, M1a, M1b, M2, M2a, M2b, M3, M3a, M3b, M4, M4a, and M4b may be wirings formed by patterning a conductive film.

In the case of FIG. 2, the wirings M5, M5a, and M5b are wirings formed by patterning a conductive film. Therefore, the wirings M5, M5a, and M5b are formed on the interlayer insulating film L6. Via portions V2 and V2a are embedded in the interlayer insulating film L6. The wiring M5 is connected to the wiring M4 via the via portion V2. The wiring M5a is connected to the wiring M4a via the via portion V2a. The wirings M5, M5a, and M5b may be damascene wirings.

In plan view, the wirings M1, M2, M3, M4, and M5 are formed in the circuit formation region CR, and the wirings M1a, M1b, M2a, M2b, M3a, M3b, M4a, M4b, M5a, and M5b are formed in the peripheral region PR.

A pad (pad electrode) PD and a wiring Moa are formed on the interlayer insulating film L7. In plan view, the pad PD is formed in the circuit formation region CR, and the wiring Moa is formed in the peripheral region PR. The pad PD is connected to the wiring M5 via a via portion V3 embedded in an opening of the interlayer insulating film L7. The wiring M6a is connected to the wiring M5a via a via portion V3a embedded in an opening of the interlayer insulating film L7.

The pad PD and the wiring Moa are formed in the same layer. That is, the pad PD and the wiring Moa are formed by patterning a common conductive film. The pad PD and the wiring Moa are not connected and are separated from each other.

The insulating protective film PA is formed on the interlayer insulating film 17 so as to cover a part of the pad PD and the wiring M6a. The protective film PA is a passivation film. The protective film PA is constituted of a single-layer insulating film or a stacked insulating film of a plurality of insulating films. In the case of FIG. 3, the protective film PA is constituted of a stacked film of a silicon nitride film NT and a silicon oxide film OX on the silicon nitride film NT.

The entire wiring M6a is covered with the protective film PA. That is, the wiring M6a is not exposed from the protective film PA. At least a part of the pad PD is exposed from an opening OP1 of the protective film PA.

The pad PD exposed from the opening OP1 of the protective film PA functions as an external terminal of the semiconductor device CP. For example, a conductive connection member such as a bonding wire can be connected to the pad PD exposed from the opening OP1 of the protective film PA.

In addition, a base metal film (not illustrated) may be formed on the pad PD, and the base metal film on the pad PD may be exposed from the opening OP1 of the protective film PA. The base metal film is constituted of, for example, a stacked film of a nickel (Ni) film and a gold (Au) film on the nickel (Ni) film.

The wiring Moa and the pad PD are preferably made of a metal material containing aluminum (Al) as a main component (main component). In this case, the pad PD is an aluminum pad, and the wiring M6a is an aluminum wiring.

Further, as illustrated in FIGS. 1, 2, and 3, the guard ring GR is formed in peripheral region PR of semiconductor device CP. The guard ring GR is formed so as to penetrate the multilayer wiring structure.

The guard ring GR is formed of wirings (metal patterns) M1a, M2a, M3a, M4a, M5a, and M6a for the guard ring and the via portions V1a, V2a, and V3a for the guard ring.

In the case of FIG. 2, the wirings M2, M2a, M2b, M3, M3a, M3b, M4, M4a, and M4b are dual damascene wirings, respectively. Therefore, each of the wirings M2a, M3a, and M4a for the guard ring integrally includes a via portion. The wirings M2, M2a, M2b, M3, M3a, M3b, M4, M4a, and M4b may be single damascene wirings.

The thickness of the wiring Moa for the guard ring and the thickness of the pad PD are the same. Therefore, the thickness of the wiring M6a for the guard ring is larger than the thickness of each of the guard ring wirings M1a, M2a, M3a, M4a, and M5a.

The guard ring GR is formed in a metal wall shape by the wirings M1a, M2a, M3a, M4a, M5a, and M6a for the guard ring and the via portions V1a, V2a, and V3a for the guard ring. That is, the guard ring GR is formed in a metal wall shape by arranging the wiring M6a, the via portion V3a, the wiring M5a, the via portion V2a, the wiring M4a, the wiring M3a, the wiring M2a, the wiring M1a, and the via portion V1a for the guard ring in the vertical direction.

As described above, in plan view, the guard ring GR is formed in the peripheral region PR of the semiconductor device CP so as to surround the circuit formation region CR. Therefore, in plan view, the wiring Moa for the guard ring, the via portion V3a, the wiring M5a, the via portion V2a, the wiring M4a, the wiring M3a, the wiring M2a, the wiring M1a, and the via portion V1a are formed in the peripheral region PR of the semiconductor device CP so as to surround the circuit formation region CR.

By providing the guard ring GR, entry of moisture from the side surface SM of the semiconductor device can be stopped by the guard ring GR. That is, the guard ring GR has a function of a barrier against entry of moisture. Therefore, by providing the guard ring GR, the reliability of the semiconductor device can be improved.

The wirings M1a, M2a, M3a, M4a, M5a, and M6a for the guard ring and the via portions V1a, V2a, and V3a are formed to form the guard ring GR, and do not have a function of connecting semiconductor elements or circuits. On the other hand, the wirings M1, M2, M3, M4, and M5 are formed to connect the semiconductor elements or circuits.

In addition, wirings M1b, M2b, M3b, M4b, and M5b, which are dummy wirings, are formed in the peripheral region PR in plan view. The dummy wiring is not electrically connected to the semiconductor element formed on the semiconductor substrate SB, is not connected to the pad PD, and does not constitute the guard ring GR. Therefore, each of the wirings M1b, M2b, M3b, M4b, and M5b is not electrically connected to any of the wirings M1, M2, M3, M4, and M5, and is not electrically connected to any of the wirings M1a, M2a, M3a, M4a, M5a, and Moa for the guard ring. Each of the wirings M1b, M2b, M3b, M4b, and M5b is a dummy wiring electrically independent from other wirings.

The trench TR is formed on a surface of the semiconductor device CP. The trench TR is adjacent to and spaced apart from the wiring M6a.

As illustrated in FIGS. 2 and 3, the trench TR is formed so as to penetrate the protective film PA and reach the inside of the multilayer wiring structure. In the case of FIGS. 2 and 3, the trench TR is formed so as to penetrate the protective film PA and reach the inside of the interlayer insulating film L7, and a bottom surface BS of the trench TR is located in the middle of the thickness of the interlayer insulating film L7. In this case, the interlayer insulating film 17 is exposed on the bottom surface BS of the trench TR. The trench TR may be formed so as to penetrate the protective film PA and the interlayer insulating film L7 and reach the inside of the interlayer insulating film L6. In this case, the interlayer insulating film L6 is exposed on the bottom surface BS of the trench TR.

The trench TR has a function of suppressing or preventing occurrence of a crack in the multilayer wiring structure in the circuit formation region CR in a dicing step (cutting step) at the time of manufacturing the semiconductor device CP. The trench TR will be described in detail later.

### <Manufacturing Process of Semiconductor Device>

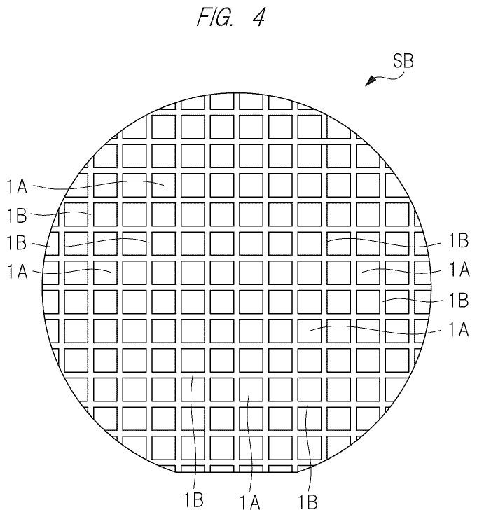

Next, an example of a manufacturing process of the semiconductor device of the present embodiment will be described. The semiconductor device CP illustrated in FIGS. 1 to 3 can be manufactured by the following manufacturing process. FIG. 4 is a plan view illustrating the semiconductor substrate SB used in the manufacturing process of the semiconductor device according to the present embodiment. FIGS. 5 to 11 are cross-sectional views of the main part in the manufacturing process of the semiconductor device of the present embodiment, and illustrate a cross section corresponding to FIG. 2.

First, as illustrated in FIGS. 4 and 5, the semiconductor substrate SB made of single crystal silicon or the like is prepared. The semiconductor substrate SB at this stage is a substantially disk-shaped semiconductor wafer.

As illustrated in FIG. 4, the semiconductor substrate SB includes a plurality of chip regions 1A, which are regions where the semiconductor chip (semiconductor device CP) is to be acquired, and a scribe region 1B between the adjacent chip regions 1A, and each chip region 1A is surrounded by the scribe region 1B in plan view. That is, in the semiconductor substrate SB, the plurality of chip regions 1A is arranged in an array, and a region between the adjacent chip regions 1A corresponds to the scribe region 1B. In the dicing step (cutting step) to be described later, each chip region 1A is divided by cutting (dicing) the semiconductor substrate SB along the scribe region 1B, and a semiconductor chip (semiconductor device CP) is acquired.

Next, a semiconductor element such as the MISFET 2 formed in each chip region 1A of the semiconductor substrate SB. Hereinafter, an example of a process of forming the MISFET 2 will be briefly described.

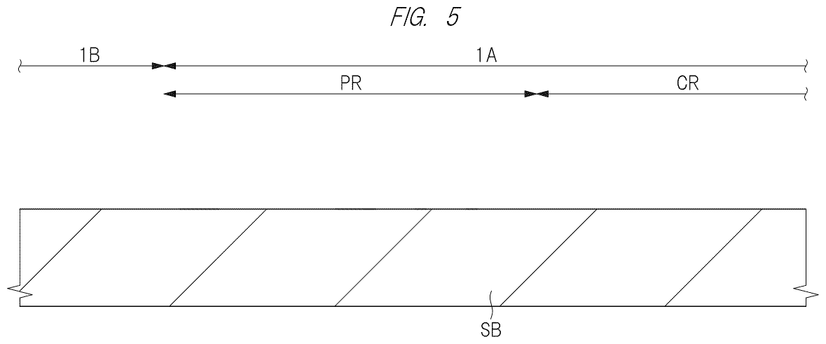

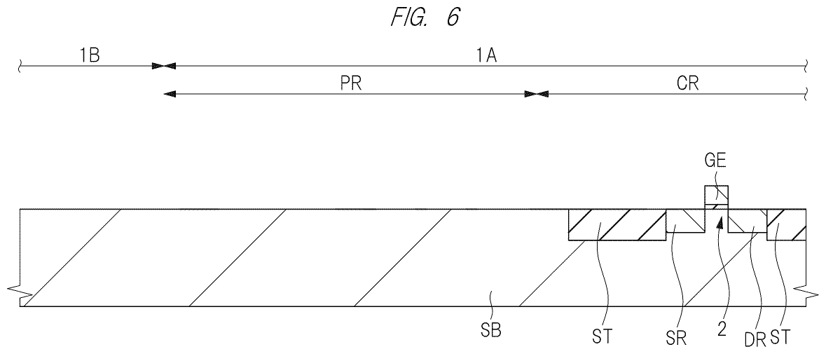

As illustrated in FIG. 6, the element isolation region ST is formed on the semiconductor substrate SB using the STI method or the like. Next, the gate electrode GE is formed on the semiconductor substrate SB via a gate insulating film. Next, the source region SR and the drain region DR are formed on the semiconductor substrate SB by ion implantation.

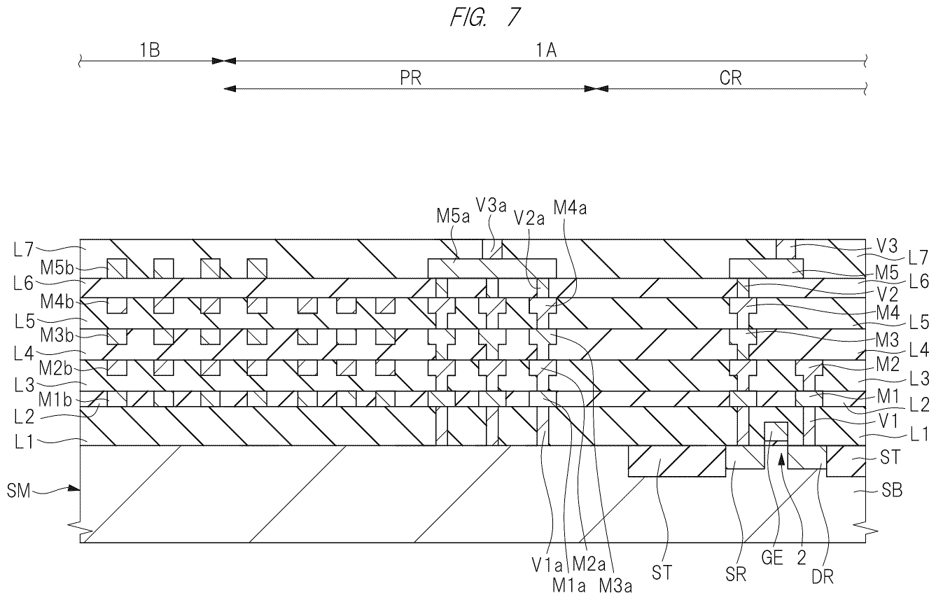

Next, as illustrated in FIG. 7, the multilayer wiring structure including the plurality of interlayer insulating films L1, L2, L3, L4, L5, L6, and L7 and the plurality of wiring layers is formed on the semiconductor substrate SB. Hereinafter, an example of a step of forming the multilayer wiring structure will be described.

As illustrated in FIG. 7, the interlayer insulating film L1 is formed on the semiconductor substrate SB so as to cover the MISFET 2. Next, the via portion V1 is embedded in the interlayer insulating film L1. Next, the interlayer insulating film L2 is formed on the interlayer insulating film L1, and then the wirings M1, M1a, and M1b are buried in the interlayer insulating film L2. Next, the interlayer insulating film L3 is formed on the interlayer insulating film L2, and then the wirings M2, M2a, and M2b are buried in the interlayer insulating film L3. Next, the interlayer insulating film L4 is formed on the interlayer insulating film L3, and then the wirings M3, M3a, and M3b are buried in the interlayer insulating film L4. Next, the interlayer insulating film L5 is formed on the interlayer insulating film L4, and then the wirings M4, M4a, and M4b are embedded in the interlayer insulating film L5. Next, after the interlayer insulating film L6 is formed on the interlayer insulating film L5, the via portions V2 and V2a are embedded in the interlayer insulating film L6. Next, the wirings M5, M5a, and M5b are formed on the interlayer insulating film L6. Next, the interlayer insulating film L7 is formed on the interlayer insulating film L6 so as to cover the wirings M5, M5a, and M5b, and then the via portions V3 and V3a are buried in the interlayer insulating film L7. In this way, the multilayer wiring structure can be formed.

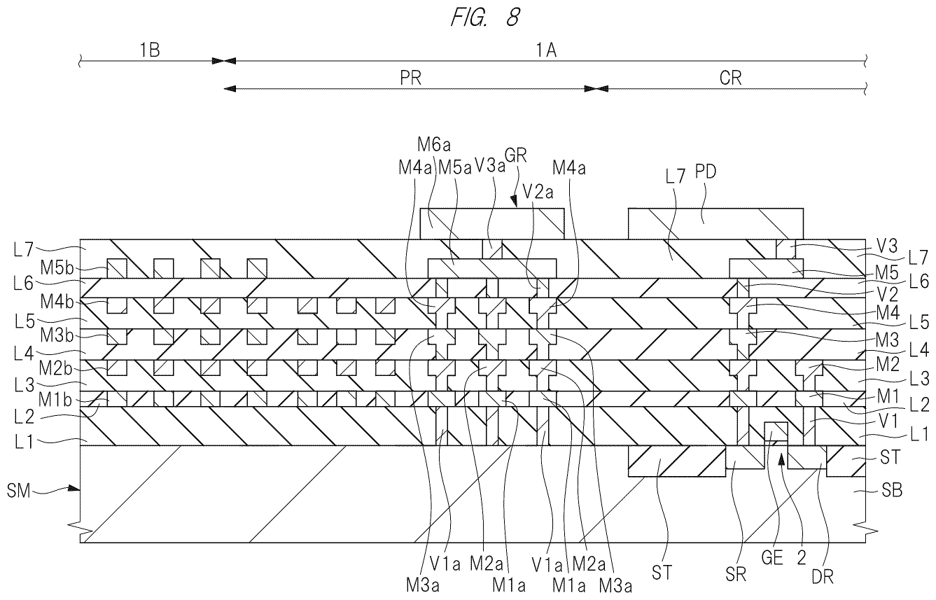

Next, as illustrated in FIG. 8, the pad PD and the wiring M6a are formed on the interlayer insulating film L7. For example, the pad PD and the wiring Moa can be formed by forming a conductive film on the interlayer insulating film L7 and then patterning the conductive film.

In plan view, the wirings M1, M2, M3, M4, and M5 and the pad PD are formed in the circuit formation region CR in each chip region 1A, and the wirings M1a, M2a, M3a, M4a, M5a, and M6a are formed in the peripheral region PR in each chip region 1A. In plan view, the wirings M1b, M2b, M3b, M4b, and M5b are formed in the scribe region 1B and the peripheral region PR in each chip region 1A.

In plan view, the guard ring GR including the wirings M1a, M2a, M3a, M4a, M5a, and M6a for the guard ring and via portions V1a, V2a, and V3a is formed in each chip region 1A. In plan view, the guard ring GR is formed in the peripheral region PR in each chip region 1A so as to surround the circuit formation region CR.

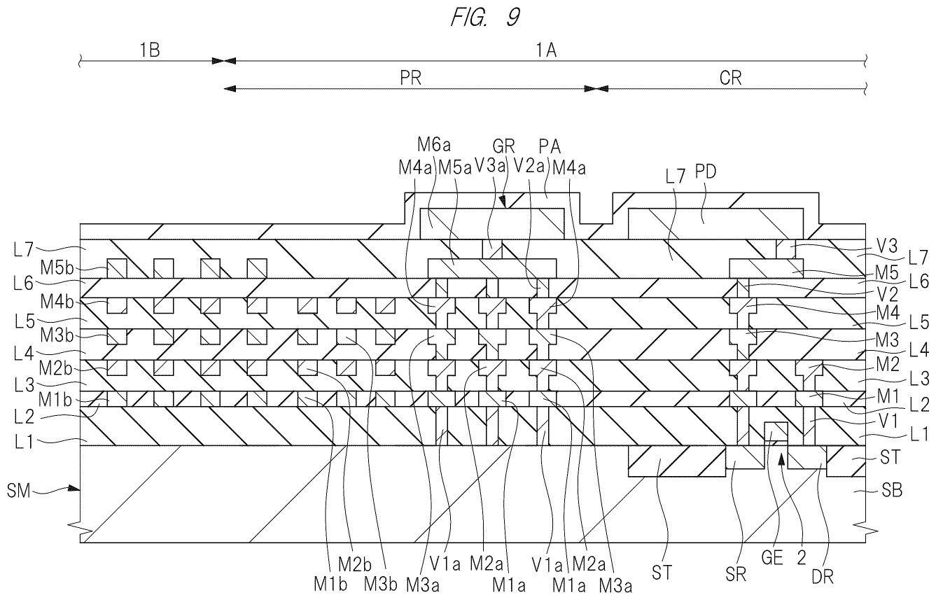

Next, as illustrated in FIG. 9, the protective film PA is formed on the interlayer insulating film L7 so as to cover the pad PD and the wiring M6a.

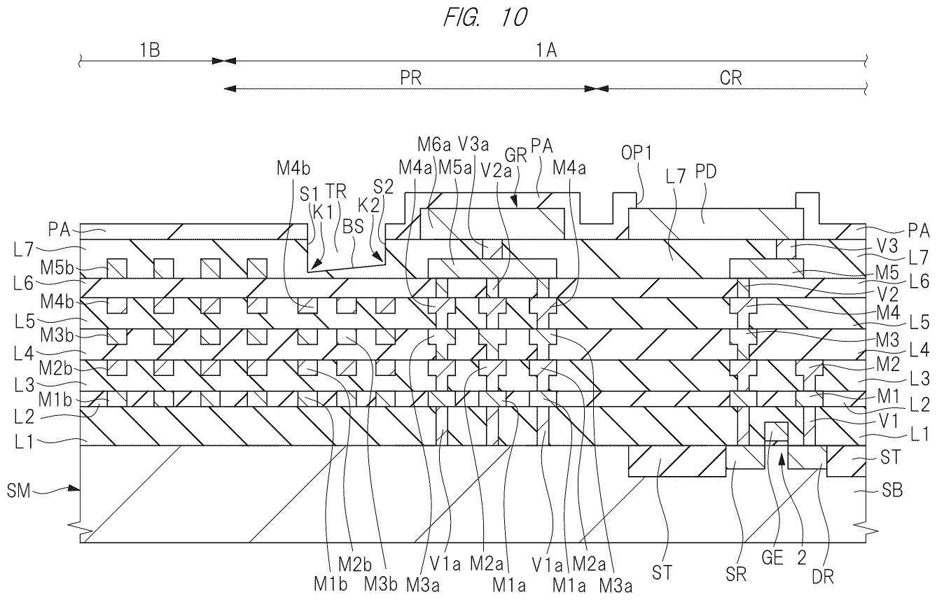

Next, as illustrated in FIG. 10, the opening OP1 and the trench TR are formed. The opening OP1 and the trench TR can be formed using a photolithography technique and an etching technique. The opening OP1 is formed so as to penetrate the protective film PA, and at least a part of the pad PD is exposed from the opening OP1 of the protective film PA.

The trench TR is formed so as to penetrate the protective film PA and reach the inside of the multilayer wiring structure. In the case of FIG. 10, the trench TR is formed so as to penetrate the protective film PA and reach the inside of the interlayer insulating film L7, and the bottom surface BS of the trench TR is located in the middle of the thickness of the interlayer insulating film L7. In this case, the interlayer insulating film L7 is exposed on the bottom surface BS of the trench TR. The trench TR may be formed so as to penetrate the protective film PA and the interlayer insulating film L7 and reach the inside of the interlayer insulating film L6. In this case, the interlayer insulating film L6 is exposed on the bottom surface BS of the trench TR.

In plan view, the trench TR is formed in the peripheral region PR in each chip region 1A so as to surround the guard ring GR.

Next, as illustrated in FIG. 11, the dicing step is performed to cut the semiconductor substrate SB and a structure (multilayer wiring structure) on the semiconductor substrate SB along the scribe region 1B. Thus, the semiconductor device CP is acquired from each chip region 1A of the semiconductor substrate SB. A cut surface obtained by dicing corresponds to the side surface SM of the semiconductor device CP. Note that the thickness of the semiconductor substrate SB may be reduced by grinding a back surface of the semiconductor substrate SB before the dicing step.

### <History of Study>

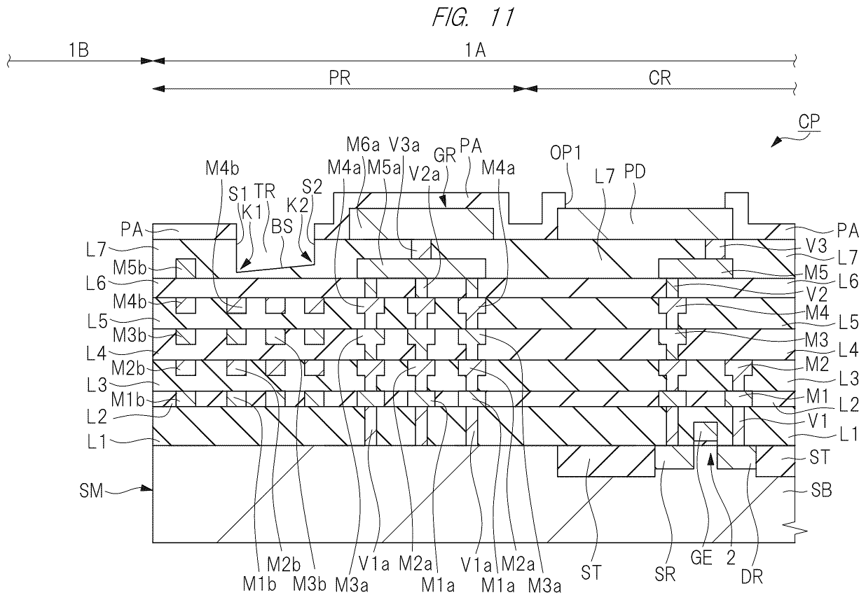

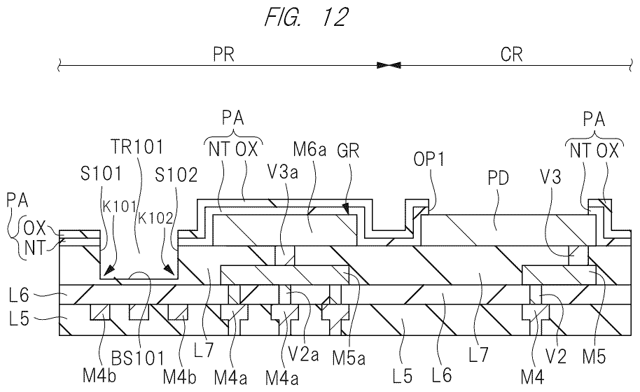

FIG. 12 is a cross-sectional view of the main part of a semiconductor device of a study example studied by the inventors of this application, and illustrates a cross section corresponding to FIG. 3.

In the semiconductor device of the study example illustrated in FIG. 12, a trench TR101 is formed instead of the trench TR. A bottom surface BS101 of the trench TR101 is parallel to the main surface of the semiconductor substrate SB. Thus, the depth of the bottom surface BS101 of the trench TR101 is constant regardless of the position in the trench TR101. The trench TR101 is formed so as to penetrate the protective film PA and reach the inside of the multilayer wiring structure.

In the dicing step at the time of manufacturing the semiconductor device, there is a concern that a crack is generated on a cut surface by a dicing blade and the crack extends to the multilayer wiring structure of the chip region 1A. Since the wirings M1, M2, M3, M4, and M5 electrically connected to the semiconductor element or the circuit are formed in the multilayer wiring structure of the circuit formation region CR, it is necessary to prevent a crack from occurring in the multilayer wiring structure of the circuit formation region CR.

The trench TR101 has a function of suppressing or preventing a crack from occurring on the cut surface by the dicing blade in the dicing step and the crack from extending to the multilayer wiring structure in the chip region 1A. This is because if the trench TR101 is formed, a crack is likely to occur below the trench TR101 with the trench TR101 as a start point or an end point. In the dicing step, by intentionally generating a crack below the trench TR101 with the trench TR101 as a start point or an end point, it is possible to suppress or prevent the crack generated in the cut surface from developing to the multilayer wiring structure in the circuit formation region CR.

However, according to the study of the inventors of this application, it has been found that the following problems occur in the case of the study example illustrated in FIG. 12.

In the case of the study example, in the dicing step, the crack is likely to occur with a corner K101 or a corner K102 of the trench TR101 as a start point or an end point.

Note that the corner K101 is formed by the bottom surface BS101 of the trench TR101 and a side surface S101 of the trench TR101. The corner K102 is formed by the bottom surface BS101 of the trench TR101 and a side surface S102 of the trench TR101. The side surface S101 of the trench TR101 and the side surface S102 of the trench TR101 face each other. In plan view, a distance (interval) between the corner K101 of the trench TR101 and the wiring M6a is larger than a distance (interval) between the corner K102 of the trench TR101 and the wiring M6a.

The probability of occurrence of a crack with the corner K101 of the trench TR101 as a start point or an end point is substantially the same as the probability of occurrence of a crack with the corner K102 of the trench TR101 as a start point or an end point. Then, as compared with a case where a crack occurs with the corner K101 of the trench TR101 as a start point or an end point, in a case where a crack occurs with the corner K102 of the trench TR101 as a start point or an end point, a distance between the crack and the circuit formation region CR is short. Therefore, as compared with the case where a crack occurs with the corner K101 of the trench TR101 as a start point or an end point, in the case where a crack occurs with the corner K102 of the trench TR101 as a start point or an end point, there is a high possibility that the crack affects the multilayer wiring structure of the circuit formation region CR. Since the wirings M1, M2, M3, M4, and M5 electrically connected to the semiconductor element or the circuit are formed in the multilayer wiring structure of the circuit formation region CR, in order to improve the reliability of the semiconductor device, it is desirable to minimize the possibility that a crack generated with the trench TR101 as a start point or an end point affects the multilayer wiring structure of the circuit formation region CR. Therefore, in order to improve the reliability of the semiconductor device, it is desirable to generate a crack not with the corner K102 of the trench TR101 but with the corner K101 of the trench TR101 as a start point or an end point in the dicing step.

Further, the trench TR101 is formed for the purpose of intentionally generating a crack with the trench TR101 as a start point or an end point in the dicing step. When the depth of the trench TR101 is shallow, a crack with the trench TR101 in the dicing step as a start point or an end point is less likely to occur. When the thickness of the protective film PA is increased, the depth of the trench TR101 is increased, and the generation of the crack with the trench TR101 as a start point or an end point is facilitated in the dicing step. However, increasing the thickness of the protective film PA increases the cost required for forming the protective film PA, and as a result, increases the manufacturing cost of the semiconductor device. Therefore, in order to suppress the manufacturing cost of the semiconductor device, it is desirable that a crack with the trench TR101 as a start point or an end point is likely to occur in the dicing step even when the depth of the trench TR101 is shallow.

Accordingly, the inventors of this application have studied the shape of the trench TR101 and found that it is desirable to form the trench TR in the present embodiment instead of the trench TR101.

### <Structure of Trench TR>

A structure of the trench TR formed in the semiconductor device according to the present embodiment will be described with reference to FIGS. 1 to 3.

As illustrated in FIG. 1, in plan view, the trench TR is formed in the peripheral region PR of semiconductor device CP so as to surround guard ring GR.

In the dicing step, by intentionally generating a crack below the trench TR with the trench TR as a start point or an end point, it is possible to suppress or prevent the crack generated on the cut surface by the dicing blade from developing to the multilayer wiring structure in the circuit formation region CR.

In the present embodiment, the bottom surface BS of the trench TR is not parallel to the main surface of the semiconductor substrate SB, but is inclined with respect to the main surface of the semiconductor substrate SB. Specifically, the bottom surface BS of the trench TR is formed to be inclined so as to be continuously deepened in a direction from the circuit formation region CR toward the peripheral region PR. In other words, the depth of the bottom surface BS of the trench TR is the smallest (shallowest) at a corner K2, gradually increases (deepest) from the corner K2 toward a corner K1, and becomes the largest (deepest) at the corner K1. As a result, in the dicing step, the crack is likely to occur not with the corner K2 of the trench TR but with the corner K1 of the trench TR as a start point or an end point.

The inclination angle of the bottom surface BS of the trench TR with respect to the main surface of the semiconductor substrate SB is, for example, equal to or more than 3 degrees. Further, the difference between the depth of the bottom surface BS at the corner K1 and the depth of the bottom surface BS at the corner K2 is, for example, equal to or more than 0.2 micrometers.

Note that the corner K1 is formed by the bottom surface BS of the trench TR and the side surface S1 of the trench TR. The corner K2 is formed by the bottom surface BS of the trench TR and the side surface S2 of the trench TR. The corner K1 and the corner K2 are positioned on opposite sides to each other via the bottom surface BS in the direction from the circuit formation region CR toward the peripheral region PR. The side surface S1 of the trench TR and the side surface S2 of the trench TR face each other, and among the side surfaces S1 and S2 of the trench TR, the side surface S2 of the trench TR is located closer to the wiring Moa than the side surface S1 of the trench TR. That is, in plan view, a distance (interval) between the side surface S1 of the trench TR and the wiring M6a is larger than a distance (interval) between the side surface S2 of the trench TR and the wiring M6a. Therefore, in plan view, a distance (interval) between the corner K1 of the trench TR and the wiring M6a is larger than a distance (interval) between the corner K2 of the trench TR and the wiring M6a. Further, in plan view, a distance (interval) between the corner K1 of the trench TR and the circuit formation region CR is larger than a distance (interval) between the corner K2 of the trench TR and the circuit formation region CR.

In the present embodiment, the probability of occurrence of a crack with the corner K1 of the trench TR as a start point or an end point is larger than the probability of occurrence of a crack with the corner K2 of the trench TR as a start point or an end point. Then, as compared with a case where a crack occurs with the corner K2 of the trench TR as a start point or an end point, in a case where a crack occurs with the corner K1 of the trench TR as a start point or an end point, the distance between the crack and the circuit formation region CR is large. Therefore, as compared with a case where a crack occurs with the corner K2 of the trench TR as a start point or an end point, in a case where a crack occurs with the corner K1 of the trench TR as a start point or an end point, there is a low possibility that the crack affects the multilayer wiring structure in the circuit formation region CR.

In the present embodiment, the bottom surface BS of the trench TR is formed to be inclined so as to be continuously deepened in the direction from the circuit formation region CR toward the peripheral region PR. Thus, in the dicing step, the probability of occurrence of a crack with the corner K2 of the trench TR as a start point or an end point can be suppressed, and the probability of occurrence of a crack with the corner K1 of the trench TR as a start point or an end point can be increased. As a result, a crack can be preferentially generated not at the corner K2 of the trench TR but at the corner K1 of the trench TR, so that it is possible to suppress or prevent the crack from affecting the multilayer wiring structure in the circuit formation region CR. Therefore, the reliability of the semiconductor device can be improved.

Further, since the bottom surface BS of the trench TR is formed to be inclined so as to be continuously deepened in the direction from the circuit formation region CR toward the peripheral region PR, the trench TR is more likely to generate a crack in the dicing step than the trench TR101. That is, when the depth of the corner K1 of the trench TR is the same as the depths of the corners K101 and K102 of the trench TR101, the trench TR is more likely to generate a crack than the trench TR101. Therefore, in the present embodiment, even when the depth of the trench TR is shallow, a crack can be generated with the corner K1 of the trench TR as a start point or an end point in the dicing step. Therefore, in the present embodiment, even when the thickness of the protective film PA is small, a crack can be generated with the corner K1 of the trench TR as a start point or an end point in the dicing step. When the thickness of the protective film PA is reduced, the time and cost required for forming the protective film PA can be suppressed, and the manufacturing cost of the semiconductor device can be suppressed. In addition, since the trench TR may be made shallow, excessive over-etching can be prevented in the etching step for forming the trench TR and the opening OP1.

The thickness of the protective film PA is, for example, 0.4 micrometers to 2.5 micrometers. As described above, even when the thickness of the protective film PA is thin, a crack having the corner K1 of the trench TR as a start point or an end point can be accurately generated in the dicing step.

In addition, the multilayer wiring structure formed on the main surface of the semiconductor substrate SB preferably includes a plurality of low-dielectric-constant insulating films. Thus, the parasitic capacitance between the plurality of wirings included in the multilayer wiring structure can be reduced. For example, a low-dielectric-constant insulating film can be used as the interlayer insulating films L2, L3, 14, and L5, and a silicon oxide film can be used as the interlayer insulating films L1, L6, and L7.

The low-dielectric-constant insulating film is made of a low-dielectric-constant material (low-k material). The low-dielectric-constant material has a lower dielectric constant than silicon oxide.

The low-dielectric-constant insulating film may be, for example, SiOF obtained by adding fluorine (F) to a silicon oxide film, SiOC obtained by adding carbon (C) to a silicon oxide film, SiCH, SiOCH, or SiCN which is a material containing carbon (C) and silicon (Si), polysiloxane constituted of silicon (Si) and oxygen (O), parylene or polyaryl ether which is an organic polymer material, methylsilsesquioxane (MSQ), methylated hydrogensilsesquioxane (MHSQ), or benzocyclobutene (BCB) which is an aromatic-containing organic material, a porous material obtained by introducing pores into these materials, or a stacked film of these materials.

The low-dielectric-constant insulating film has low adhesion. For this reason, when the multilayer wiring structure includes a plurality of low-dielectric-constant insulating films, a crack is likely to extend through the interface between the insulating films, and thus there is a concern that the crack extends to the multilayer wiring structure in the circuit formation region CR. However, even in a case where the multilayer wiring structure includes a plurality of low-dielectric-constant insulating films, by forming the trench TR, it is possible to accurately prevent the crack from extending to the multilayer wiring structure of the circuit formation region CR.

### <Forming Step of Trench TR>

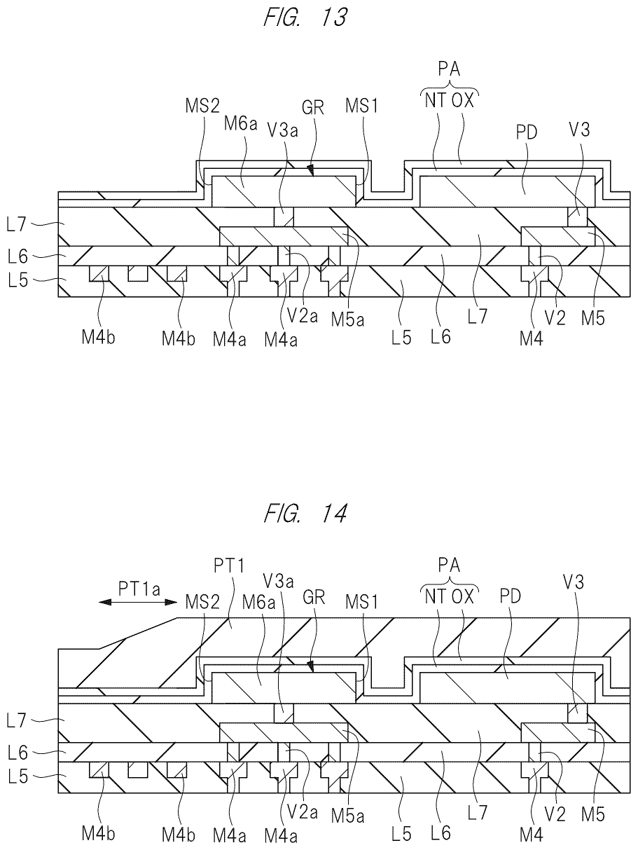

An example of a process of forming the trench TR will be described with reference to FIGS. 13 to 17. FIGS. 13 to 17 are cross-sectional views of the main part in the manufacturing process of the semiconductor device according to the present embodiment.

As illustrated in FIGS. 9 and 13, the protective film PA is formed on the interlayer insulating film L7 so as to cover the pad PD and the wiring M6a. FIG. 13 is a cross-sectional view illustrating the same step as FIG. 9, and illustrates a structure above the interlayer insulating film L4.

The wiring Moa has a side surface MS1 and a side surface MS2 opposite to the side surface MS1. The side surface MS1 of the wiring Moa is a side surface of the inner periphery of the wiring M6a, and the side surface MS2 of the wiring Moa is a side surface of the outer periphery of the wiring M6a. In plan view, the pad PD faces the side surface MS1 of the wiring M6a. In plan view, the side surface MS2 of the wiring M6a faces the scribe region 1B.

In the case of FIG. 13, the protective film PA is constituted of a stacked film of the silicon nitride film NT and the silicon oxide film OX on the silicon nitride film NT. Each of the silicon nitride film NT and the silicon oxide film OX can be formed using, for example, a CVD method.

Next, as illustrated in FIG. 14, a photoresist layer PT1 is formed on the protective film PA.

A step caused by the wiring M6a is formed on a surface of the protective film PA, and the photoresist layer PT1 is formed so as to cover the step. Reflecting this, the photoresist layer PT1 has a region PT1a in which the thickness of the photoresist layer PT1 gradually decreases as a distance from the side surface MS2 of the wiring M6a increases between the wiring M6a and the scribe region 1B in plan view. The region PT1a is located near the wiring M6a. The thickness of the photoresist layer PT1 in the region PT1a is the largest near the side surface MS2 of the wiring M6a, and gradually decreases as a distance from the side surface MS2 of the wiring M6a increases. That is, in the region PT1a, the photoresist layer PT1 has a trailing shape.

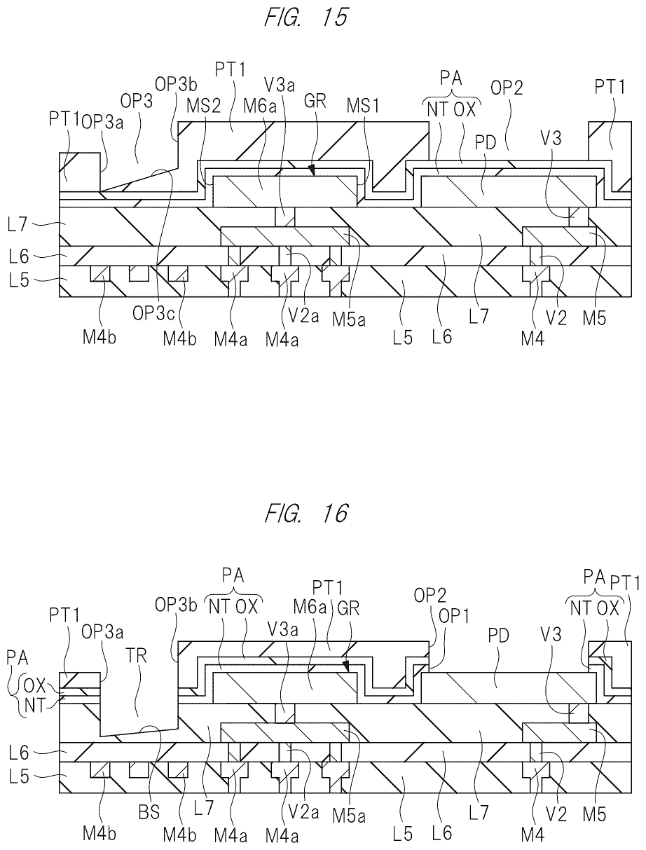

Next, as illustrated in FIG. 15, after the photoresist layer PT1 is exposed using a photomask (not illustrated), the photoresist layer PT1 is developed to form an opening OP2 and an opening OP3 in the photoresist layer PT1.

The opening OP2 is the opening for forming the opening OP1. In plan view, the opening OP2 is formed in an opening OP1 formation scheduled region. Therefore, in plan view, the opening OP2 is included in the pad PD. The photoresist layer PT1 does not remain at the bottom of the opening OP2, and the opening OP2 is formed so as to penetrate the photoresist layer PT1.

The opening OP3 is an opening or a trench for forming the trench TR. In plan view, the opening OP3 is formed in a trench TR formation scheduled region. In plan view, the opening OP3 is formed in the region PT1a of the photoresist layer PT1.

In plan view, the shortest distance (nearest distance) between the opening OP3 and the wiring M6a is, for example, 0.1 micrometers to 1.5 micrometers. The trench TR is formed so as to be aligned with the opening OP3. Thus, in plan view, the shortest distance (nearest distance) between the trench TR and the wiring M6a is 0.1 micrometers to 1.5 micrometers. Further, the thickness of the wiring M6a is, for example, 0.5 micrometers to 1.5 micrometers.

The opening OP3 has a side surface OP3a and a side surface OP3b facing each other. Among the side surfaces OP3a and OP3b of the opening OP3, the side surface OP3b is located closer to the wiring M6a than the side surface OP3a. That is, in plan view, a distance (interval) between the side surface OP3a of the opening OP3 and the wiring Moa is larger than a distance (interval) between the side surface OP3b of the opening OP3 and the wiring M6a.

A part of the photoresist layer PT1 remains at the bottom of the opening OP3. This can be implemented by adjusting the exposure amount in the exposure processing of the photoresist layer PT1.

In plan view, the opening OP3 is formed in the region PT1a of the photoresist layer PT1. Reflecting this, at the bottom of the opening OP3, the remaining thickness of the photoresist layer PT1 is the largest near the side surface OP3b of the opening OP3, and gradually decreases in a direction from the side surface OP3b of the opening OP3 toward the side surface OP3a of the opening OP3. As a result, a bottom surface OP3c of opening OP3 is inclined with respect to the main surface of the semiconductor substrate SB. Specifically, the bottom surface OP3c of the opening OP3 is inclined so as to be gradually deepened in the direction from the side surface OP3b of the opening OP3 toward the side surface OP3a of the opening OP3.

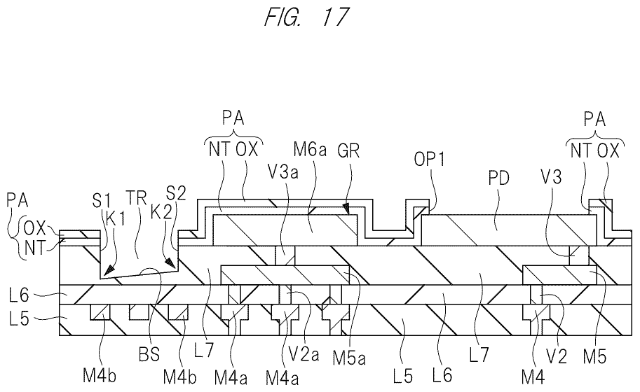

Next, as illustrated in FIG. 16, the opening OP1 and the trench TR are formed by etching the protective film PA and the interlayer insulating film L7 using the photoresist layer PT1 as an etching mask. Hereinafter, this etching step is referred to as an etching step using the photoresist layer PT1. The opening OP1 is formed by etching the protective film PA below the opening OP2, and the trench TR is formed by etching the protective film PA and the multilayer wiring structure below the opening OP3. Thereafter, as illustrated in FIG. 17, the photoresist layer PT1 is removed by ashing or the like.

In the etching step using the photoresist layer PT1, the protective film PA exposed from the opening OP2 of the photoresist layer PT1 is etched to form the opening OP1 of the protective film PA. Thus, the opening OP1 of the protective film PA is formed in alignment with the opening OP2 of the photoresist layer PT1. A part of the pad PD is exposed from the opening OP1 of the protective film PA.

In the etching step using the photoresist layer PT1, the photoresist layer PT1 remaining at the bottom of the opening OP3 is etched and removed, and moreover, the protective film PA exposed from the opening OP3 of the photoresist layer PT1 and the interlayer insulating film L7 under the protective film PA are etched. Thus, the trench TR is formed so as to penetrate the protective film PA and reach the inside of the multilayer wiring structure. The trench TR is formed in alignment with the opening OP3 of the photoresist layer PT1. That is, the side surface S1 of the trench TR is formed in alignment with the side surface OP3a of the opening OP3 of the photoresist layer PT1, and the side surface S2 of the trench TR is formed in alignment with the side surface OP3b of the opening OP3 of the photoresist layer PT1.

As described above, before the etching step using the photoresist layer PT1, the remaining thickness of the photoresist layer PT1 at the bottom of the opening OP3 of the photoresist layer PT1 gradually decreased in the direction from the side surface OP3b of the opening OP3 toward the side surface OP3a of the opening OP3. Reflecting this, after the etching step using the photoresist layer PT1, the bottom surface BS of the trench TR is inclined with respect to the main surface of the semiconductor substrate SB. Specifically, the bottom surface BS of the trench TR is inclined so as to be gradually deepened in a direction from the side surface S2 of the trench TR toward the side surface S1 of the trench TR.

In this way, the trench TR and the opening OP1 can be formed. The bottom surface BS of the trench TR is formed to be inclined so as to be continuously deepened in the direction from the side surface S2 of the trench TR toward the side surface S1 of the trench TR. In other words, the depth of the bottom surface BS of the trench TR is shallowest at the corner K2, gradually becomes deeper from the corner K2 toward the corner K1, and becomes deepest at the corner K1. As a result, in the dicing step to be performed later, a crack is likely to occur with the corner K1 of the trench TR as a start point or an end point.

Note that the direction from the side surface S2 to the side surface S1 of the trench TR, the direction from the circuit formation region CR to the peripheral region PR, and the direction from the circuit formation region CR to the scribe region 1B are the same.

Thereafter, by performing the dicing step as described above, the semiconductor substrate SB and the structure on the semiconductor substrate SB are cut along the scribe region 1B.

### Modification

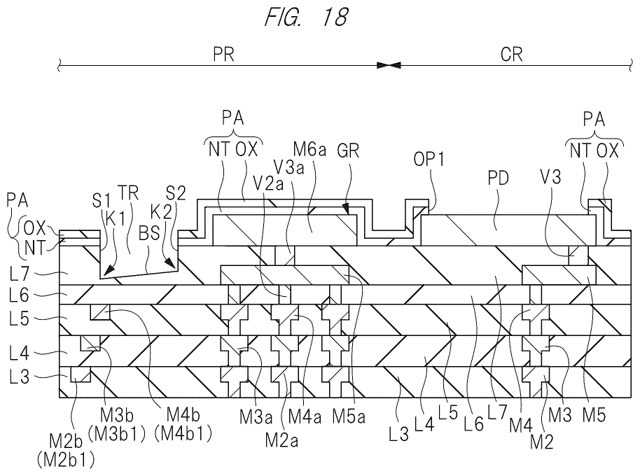

FIG. 18 is a cross-sectional view of the main part illustrating a semiconductor device according to a modification of the present embodiment. In FIG. 18, illustration of a structure below the interlayer insulating film L3 is omitted.

In the case of the modification illustrated in FIG. 18, a wiring M4b (hereinafter, referred to as a wiring M4b1) which is a dummy wiring is arranged below the corner K1 of the trench TR. In addition, the wiring M4b, which is a dummy wiring, is not disposed below the corner K2 of the trench TR. Therefore, in plan view, the corner K1 of the trench TR overlaps the wiring M4b1, but the corner K2 of the trench TR does not overlap the wiring M4b.

In addition, a wiring M3b (hereinafter, referred to as a wiring M3b1) that is a dummy wiring is arranged below the wiring M4b1 arranged below the corner K1 of the trench TR, and a wiring M2b (hereinafter, referred to as a wiring M2b1) that is a dummy wiring is arranged below the wiring M3b1. In plan view, the shape of each of the wirings M4b1, M3b1, and M2b1 is, for example, a rectangular isolated pattern or a linear pattern.

Note that, in plan view, the wiring M3b1 partially overlaps the wiring M4b1, but the wiring M3b1 is deviated from the wiring M4b1 in a direction from the circuit formation region CR toward the peripheral region PR. In plan view, the amount of deviation of the wiring M3b1 from the wiring M4b1 is, for example, half or less of the width of the wiring M3b1. In addition, in plan view, the wiring M2b1 partially overlaps the wiring M3b1, but the wiring M2b1 is deviated from the wiring M3b1 in the direction from the circuit formation region CR toward the peripheral region PR. In plan view, the amount of deviation of the wiring M2b1 from the wiring M3b1 is, for example, half or less of the width of the wiring M2b1.

Thus, in the dicing step, it is possible to guide a crack that has entered from the cut surface by the dicing blade to reach the corner K1 of the trench TR along the surface of the dummy wiring (here, the wiring M2b1, the wiring M3b1, and the wiring M4b1). As a result, it is possible to suppress or prevent the crack entering from the cut surface by the dicing blade from extending to the multilayer wiring structure in the circuit formation region CR. Therefore, the performance of the semiconductor device can be improved.

The technical idea of the modification illustrated in FIG. 18 can also be applied to the second embodiment and the third embodiment described later.

### Second Embodiment

A semiconductor device of a second embodiment is different from the semiconductor device of the first embodiment in the structure of the trench TR. Other than that, the semiconductor device of the second embodiment has a structure similar to that of the semiconductor device of the first embodiment.

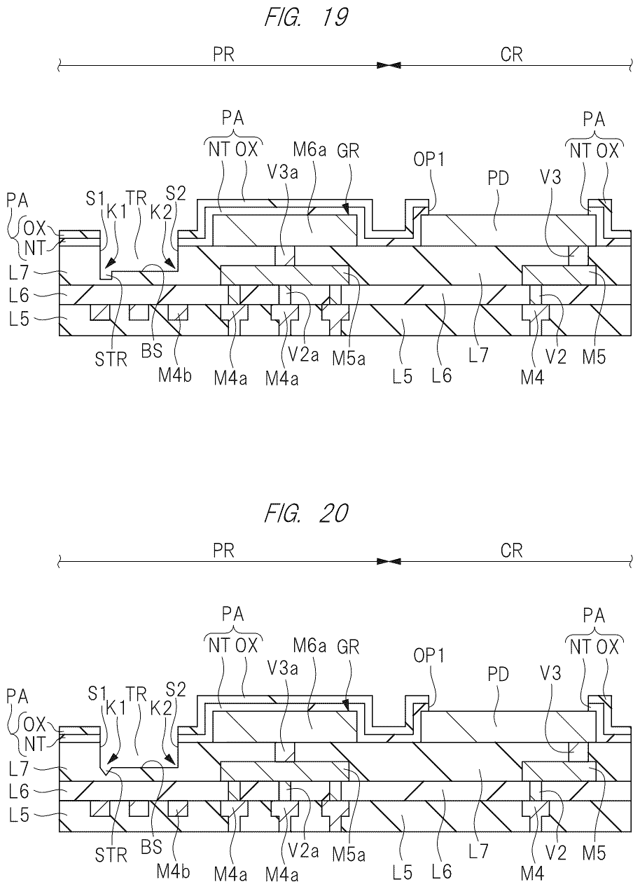

The structure of the trench TR formed in the semiconductor device of the second embodiment will be described with reference to FIG. 19. FIG. 19 is a cross-sectional view of the main part of the semiconductor device of the second embodiment, and illustrates a cross-sectional view corresponding to FIG. 3. Similarly to FIG. 3, also in FIG. 19, the structure below the interlayer insulating film L5 is not illustrated. Further, in the following description, the difference between the trench TR in the second embodiment and the trench TR in the first embodiment will be mainly described.

In the second embodiment, the bottom surface BS of the trench TR is substantially parallel to the main surface of the semiconductor substrate SB. In the second embodiment, a sub-trench STR is formed at the corner K1 of the trench TR. No sub-trench is formed at the corner K2 of the trench TR.

The width of the sub-trench STR is smaller than the width of the trench TR. Here, each of the width of the trench TR and the width of the sub-trench STR corresponds to a width in a direction parallel to the main surface of the semiconductor substrate SB and in a direction from the side surface S1 to the side surface S2 of the trench TR. The width of the trench TR is a distance (interval) between the side surface S1 and the side surface S2 of the trench TR.

In the second embodiment, the sub-trench STR is formed at the corner K1 of the trench TR, and the sub-trench is not formed at the corner K2 of the trench TR. As a result, in the dicing step, the crack is likely to occur not with the corner K2 of the trench TR but with the corner K1 of the trench TR as a start point or an end point.

In the second embodiment, the sub-trench STR is formed at the corner K1 of the trench TR, and the sub-trench is not formed at the corner K2 of the trench TR. Thus, in the dicing step, a crack can be preferentially generated with the sub-trench STR of the trench TR as a start point or an end point. As a result, it is possible to suppress or prevent the crack from affecting the multilayer wiring structure in the circuit formation region CR. Therefore, the reliability of the semiconductor device can be improved.

Further, in the second embodiment, since the sub-trench STR is formed at the corner K1 of the trench TR, the trench TR in the second embodiment is more likely to generate a crack in the dicing step than the trench TR101 in the study example. That is, when the depth of the bottom surface BS of the trench TR is the same as the depth of the bottom surface BS101 of the trench TR101, the trench TR is more likely to generate a crack than the trench TR101. Thus, in the second embodiment, even when the depth of the trench TR is shallow, it is possible to generate a crack having the sub-trench STR of the trench TR as a start point or an end point in the dicing step. Therefore, in the second embodiment, even when the thickness of the protective film PA is small, it is possible to generate a crack having the sub-trench STR of the trench TR as a start point or an end point in the dicing step. When the thickness of the protective film PA is reduced, the cost required for forming the protective film PA can be and suppressed, the manufacturing cost of the semiconductor device can be suppressed. In addition, since the trench TR may be made shallow, excessive over-etching can be prevented in the etching step for forming the trench TR and the opening OP1.

The trench TR has a slit shape. In the case of FIG. 19, the sub-trench STR also has a slit shape. That is, as illustrated in FIG. 19, in a cross-sectional view perpendicular to the extending direction of the trench TR, a bottom portion of the trench TR excluding the sub-trench STR is flat, and a bottom portion of the sub-trench STR is also flat.

FIG. 20 is a cross-sectional view of the main part of a semiconductor device according to a modification of the second embodiment; In the case of FIG. 20, the sub-trench STR has a spike shape. That is, as illustrated in FIG. 20, in a cross-sectional view perpendicular to the extending direction of the trench TR, the shape of the sub-trench STR is a shape having a sharp tip portion. Note that the bottom portion of the sub-trench STR corresponds to a tip portion of a spike shape.

In both the case of FIG. 19 and the case of FIG. 20, a crack can be preferentially generated with the sub-trench STR of the trench TR as a start point or an end point in the dicing step.

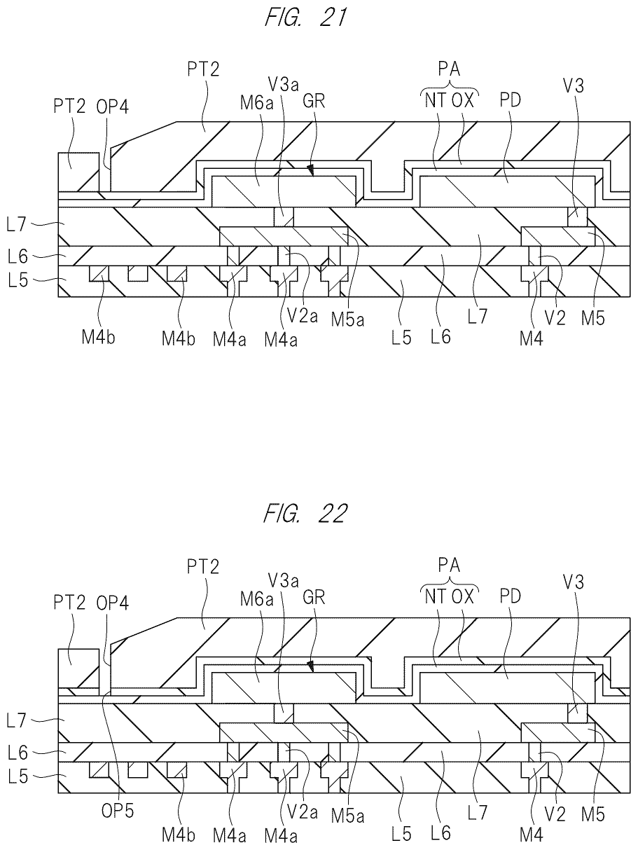

Next, an example of a process of forming the trench TR in the second embodiment will be described with reference to FIGS. 13 and 21 to 26. FIGS. 21 to 26 are cross-sectional views of the main part in the manufacturing process of the semiconductor device of the second embodiment.

As in the first embodiment, also in the second embodiment, as illustrated in FIG. 13, the protective film PA is formed on the interlayer insulating film L7 so as to cover the pad PD and the wiring M6a.

Next, as illustrated in FIG. 21, after a photoresist layer PT2 is formed on the protective film PA, the photoresist layer PT2 is subjected to exposure processing and development processing to form an opening OP4 in the photoresist layer PT2. The opening OP4 is formed so as to penetrate the photoresist layer PT2. In plan view, the opening OP4 is formed in a sub-trench STR formation scheduled region. The opening OP2 is not formed in the photoresist layer PT2.

Next, as illustrated in FIG. 22, the silicon oxide film OX exposed from the opening OP4 of the photoresist layer PT2 is etched to form an opening OP5 in the silicon oxide film OX. The opening OP5 of the silicon oxide film OX is formed so as to match the opening OP4 of the photoresist layer PT2. Thus, the opening OP5 of the silicon oxide film OX is formed in the sub-trench STR formation scheduled region.

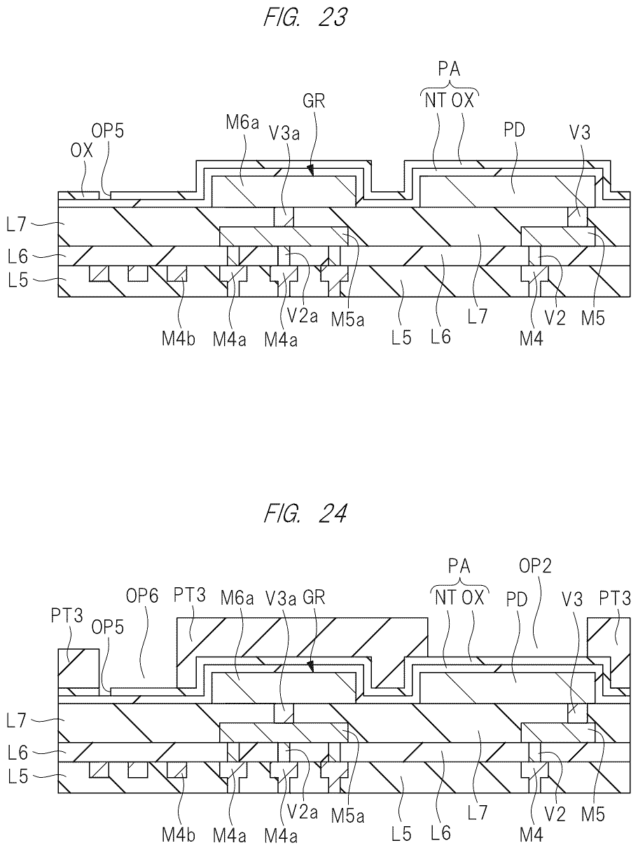

Next, as illustrated in FIG. 23, the photoresist layer PT2 is removed by ashing or the like.

Next, as illustrated in FIG. 24, after a photoresist layer PT3 is formed on the protective film PA, the photoresist layer subjected to exposure processing and development PT3 is processing to form the opening OP2 and an opening OP6 in the photoresist layer PT3. The opening OP2 and the opening OP6 are formed so as to penetrate the photoresist layer PT3.

The opening OP6 is an opening for forming the trench TR. In plan view, the opening OP3 is formed in the trench TR formation scheduled region. Therefore, in plan view, the opening OP5 of the silicon oxide film OX is included in the opening OP6 of the photoresist layer PT3.

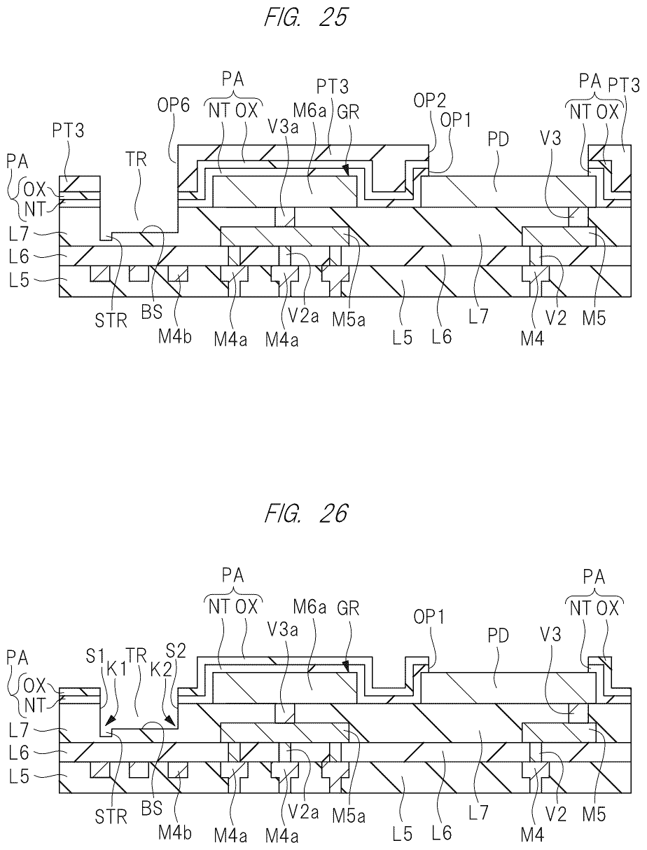

Next, as illustrated in FIG. 25, the opening OP1 and the trench TR are formed by etching the protective film PA and the interlayer insulating film L7 using the photoresist layer PT3 as an etching mask. Hereinafter, this etching step is referred to as an etching step using the photoresist layer PT3. Thereafter, as illustrated in FIG. 26, the photoresist layer PT3 is removed by ashing or the like.

In the etching step using the photoresist layer PT3, the protective film PA exposed from the opening OP2 of the photoresist layer PT3 is etched to form the opening OP1 of the protective film PA. A part of the pad PD is exposed from the opening OP1 of the protective film PA.

In the etching step using the photoresist layer PT3, the protective film PA exposed from the opening OP6 of the photoresist layer PT3 and the interlayer insulating film L7 under the protective film PA are etched to form the trench TR and the sub-trench STR. After the opening OP5 of the silicon oxide film OX is formed in the sub-trench STR formation scheduled region, the sub-trench STR is formed at the corner K1 of the trench TR, reflecting the etching step using the photoresist layer PT3.

In this way, the trench TR and the opening OP1 can be formed. The sub-trench STR is formed at the corner K1 of the trench TR, and the sub-trench is not formed at the corner K2 of the trench TR. As a result, in the dicing step to be performed later, a crack is likely to occur with the sub-trench STR of the trench TR as a start point or an end point.

Thereafter, by performing the dicing step as described above, the semiconductor substrate SB and the structure on the semiconductor substrate SB are cut along the scribe region 1B.

### Third Embodiment

A semiconductor device of the third embodiment is different from the semiconductor devices of the first and second embodiments in the structure of the trench TR. Other than that, the semiconductor device of the third embodiment has a structure similar to that of the semiconductor devices of the first and second embodiments.

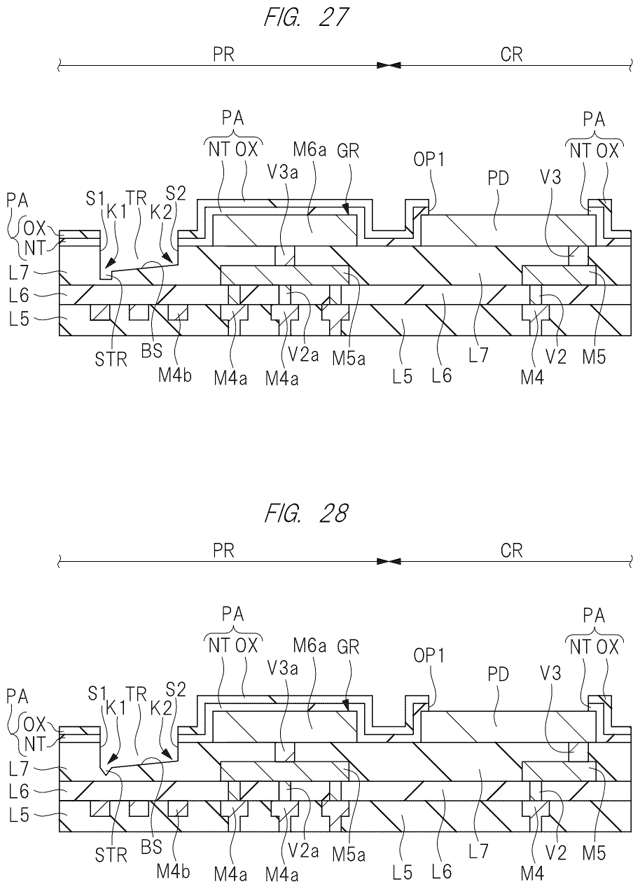

The structure of the trench TR formed in the semiconductor device of the third embodiment will be described with reference to FIG. 27. FIG. 27 is a cross-sectional view of the main part of the semiconductor device of the third embodiment, and illustrates cross-sectional views corresponding to FIGS. 3 and 19. Similarly to FIG. 3, also in FIG. 27, the structure below the interlayer insulating film L5 is not illustrated. Further, in the following description, the difference between the trench TR in the third embodiment and the trench TR in the first embodiment will be mainly described.

The trench TR in the third embodiment corresponds to the case where the sub-trench STR in the second embodiment is formed in the trench TR in the first embodiment. That is, similarly to the first embodiment, also in the third embodiment, the bottom surface BS of the trench TR is inclined with respect to the main surface of the semiconductor substrate SB. Further, similarly to the second embodiment, also in the third embodiment, the sub-trench STR is formed at the corner K1 of the trench TR. No sub-trench is formed at the corner K2 of the trench TR.

Therefore, as illustrated in FIG. 27, between the corner K2 of the trench TR and the sub-trench STR, the bottom surface BS of the trench TR is formed to be inclined so as to be continuously deepened in the direction from the circuit formation region CR toward the peripheral region PR. In other words, the depth of the bottom surface BS of the trench TR is the smallest (shallowest) at the corner K2, and gradually becomes larger (deeper) from the corner K2 toward the sub-trench STR.

In the third embodiment, since the bottom surface BS of the trench TR is inclined similarly to that in the first embodiment, and the sub-trench STR is formed at the corner K1 of the trench TR, in the dicing step, the crack is likely to occur with the sub-trench STR formed at the corner K1 of the trench TR as a start point or an end point. That is, as compared with the trench TR in the first embodiment and the trench TR in the second embodiment, the trench TR in the third embodiment is more likely to generate a crack in the dicing step. Thus, it is possible to further suppress or prevent the crack from affecting the multilayer wiring structure in the circuit formation region CR. Therefore, the reliability of the semiconductor device can be further improved.

In addition, in the third embodiment, even when the depth of the trench TR is shallow, it is possible to generate a crack with the sub-trench STR of the trench TR as a start point in the dicing step. Therefore, in the third embodiment, even when the thickness of the protective film PA is small, it is possible to generate a crack with the sub-trench STR of the trench TR as a start point in the dicing step. When the thickness of the protective film PA is reduced, the cost required for forming the protective film PA can be suppressed, and the manufacturing cost of the semiconductor device can be suppressed. In addition, since the trench TR may be made shallow, excessive over-etching can be prevented in the etching step for forming the trench TR and the opening OP1.

Similarly to the sub-trench STR of FIG. 19, the sub-trench STR of FIG. 27 has a slit shape.

FIG. 28 is a cross-sectional view of the main part of a semiconductor device according to a modification of the third embodiment. Similarly to the sub-trench STR of FIG. 20, the sub-trench STR of FIG. 28 has a spike shape. In both the case of FIG. 27 and the case of FIG. 28, a crack can be preferentially generated with the sub-trench STR of the trench TR as a start point or an end point in the dicing step.

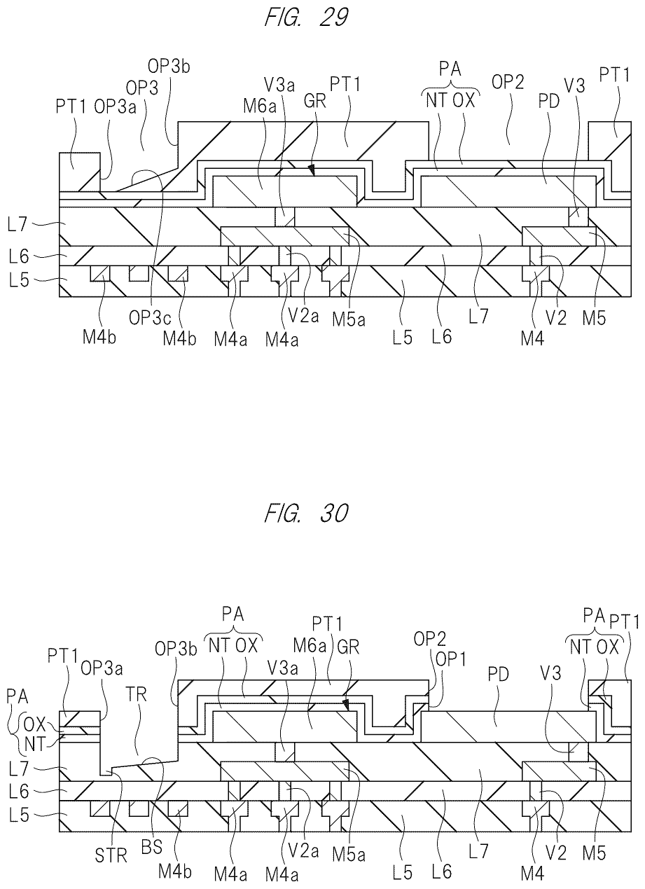

Next, an example of a process of forming the trench TR in the third embodiment will be described with reference to FIGS. 13, 14, and 29 to 31. FIGS. 29 to 31 are cross-sectional views of the main part in the manufacturing process of the semiconductor device of the third embodiment.

Similarly to the first embodiment, also in the third embodiment, as illustrated in FIG. 13, the protective film PA is formed on the interlayer insulating film L7 so as to cover the pad PD and the wiring M6a.

Next, similarly to the first embodiment, also in the third embodiment, as illustrated in FIG. 14, the photoresist layer PT1 is formed on the protective film PA.

Next, as illustrated in FIG. 29, after the photoresist layer PT1 is exposed using a photomask (not illustrated), the photoresist layer PT1 is developed to form the opening OP2 and the opening OP3 in the photoresist layer PT1.

The opening OP2 in the third embodiment is similar to the opening OP2 in the first embodiment. The opening OP3 in the third embodiment is different from the opening OP3 in the first embodiment in the following points.

In plan view, the photoresist layer PT1 does not remain in the sub-trench STR formation scheduled region. That is, at the bottom of the opening OP3, the photoresist layer PT1 does not remain near the side surface OP3a of the opening OP3, and the protective film PA is exposed. Between the side surface OP3b of the opening OP3 and the sub-trench STR formation scheduled region in plan view, the remaining thickness of the photoresist layer PT1 is the largest near the side surface OP3b of the opening OP3, and gradually decreases in the direction from the side surface OP3b of the opening OP3 toward the side surface OP3a of the opening OP3. As a result, between the side surface OP3b of the opening OP3 and the sub-trench STR formation scheduled region in the plan view, the bottom surface OP3c of the opening OP3 is inclined so as to be gradually deepened in the direction from the side surface OP3b of the opening OP3 toward the side surface OP3a of the opening OP3. The bottom surface OP3c of the opening OP3 is formed by a surface of the photoresist layer PT1 between the side surface OP3b of the opening OP3 and the sub-trench STR formation scheduled region in plan view. On the other hand, in the sub-trench STR formation scheduled region, the bottom surface OP3c of the opening OP3 is formed by an upper surface of the protective film PA.

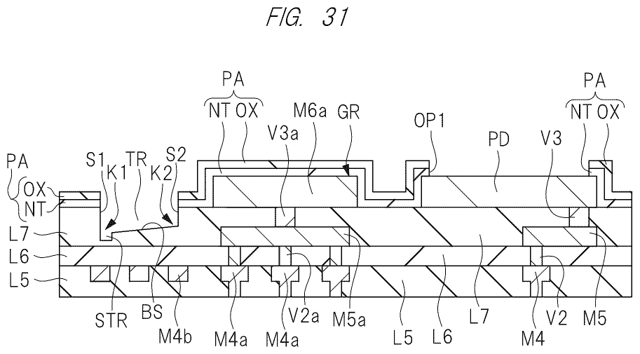

Next, as illustrated in FIG. 30, the opening OP1 and the trench TR are formed by etching the protective film PA and the interlayer insulating film L7 using the photoresist layer PT1 as an etching mask. Hereinafter, this etching step is referred to as an etching step using the photoresist layer PT1. Thereafter, as illustrated in FIG. 31, the photoresist layer PT1 is removed by ashing or the like.

In the etching step using the photoresist layer PT1, the protective film PA exposed from the opening OP2 of the photoresist layer PT1 is etched to form the opening OP1 of the protective film PA. A part of the pad PD is exposed from the opening OP1 of the protective film PA.

In the etching step using the photoresist layer PT1, the photoresist layer PT1 remaining at the bottom of the opening OP3 is etched and removed, and moreover, the protective film PA exposed from the opening OP3 of the photoresist layer PT1 and the interlayer insulating film L7 under the protective film PA are etched. Thus, the trench TR is formed so as to penetrate the protective film PA and reach the inside of the multilayer wiring structure.

As described above, before the etching step using the photoresist layer PT1, between the side surface OP3b of the opening OP3 and the sub-trench STR formation scheduled region in plan view, the remaining thickness of the photoresist layer PT1 gradually decreases in the direction from the side surface OP3b of the opening OP3 toward the side surface OP3a of the opening OP3. Reflecting this, after the etching step using the photoresist layer PT1, between the side surface S2 of the trench TR and the sub-trench STR in plan view, the bottom surface BS of the trench TR is inclined so as to gradually become deeper in the direction from the side surface S2 of the trench TR toward the side surface S1 of the trench TR. Further, before the etching step using the photoresist layer PT1, the sub-trench STR is formed at the corner K1 of the trench TR by the etching step using the photoresist layer PT1, reflecting that the photoresist layer PT1 does not remain in the sub-trench STR formation scheduled region in plan view.

In this manner, the opening OP1, the trench TR, and the sub-trench STR can be formed. Between the side surface S2 of the trench TR and the sub-trench STR, the bottom surface BS of the trench TR is formed to be inclined so as to be continuously deepened in the direction from the side surface S2 of the trench TR toward the side surface S1 of the trench TR. In other words, the depth of the bottom surface BS of the trench TR is shallowest at the corner K2, and gradually deepens as approaching the sub-trench STR from the corner K2. Then, the sub-trench STR is formed at the corner K1 of the trench TR. As a result, in the dicing step to be performed later, a crack is likely to occur with the sub-trench STR formed at the corner K1 of the trench TR as a start point or an end point.

Thereafter, by performing the dicing step as described above, the semiconductor substrate SB and the structure on the semiconductor substrate SB are cut along the scribe region 1B.

Although the invention made by the inventors of this application has been specifically described based on the embodiments, the present invention is not limited to the embodiments, and it goes without saying that various modifications can be made without departing from the gist of the invention.

What is claimed is:

1. A semiconductor device comprising:
a semiconductor substrate having a main surface;
a circuit formation region formed on the main surface;
a peripheral region formed on an outer periphery of the circuit formation region in a plan view;
a multilayer wiring structure formed on the main surface and including a plurality of insulating films and a plurality of wiring layers;
a guard ring formed in the peripheral region so as to surround the circuit formation region and so as to penetrate the multilayer wiring structure;
a pad formed on the multilayer wiring structure;
a protective film formed so as to cover the multilayer wiring structure, the guard ring, and the pad; and
a trench formed in the peripheral region so as to surround the guard ring and formed so as to penetrate the protective film and reach an inside of the multilayer wiring structure,
wherein the guard ring includes a first wiring formed on the multilayer wiring structure so as to surround the circuit formation region,
wherein the trench is spaced apart from and adjacent to the first wiring, and
wherein a bottom surface of the trench is formed to be inclined so as to be continuously deepened in a first direction from the circuit formation region toward the peripheral region.

2. The semiconductor device according to claim 1,
wherein an inclination angle of the bottom surface of the trench is equal to or more than 3 degrees with respect to the main surface of the semiconductor substrate.

3. The semiconductor device according to claim 1,
wherein the trench has a first corner and a second corner located on opposite sides to each other via the bottom surface in the first direction,
wherein a distance between the first corner and the first wiring is larger than a distance between the second corner and the first wiring in a plan view, and
wherein a sub-trench is formed at the first corner of the trench.

4. The semiconductor device according to claim 3,
wherein the sub-trench has a slit shape.

5. The semiconductor device according to claim 3,
wherein the sub-trench has a spike shape.

6. The semiconductor device according to claim 1,
wherein the trench has a first corner and a second corner located on opposite sides to each other via the bottom surface in the first direction,
wherein a distance between the first corner and the first wiring is larger than a distance between the second corner and the first wiring in a plan view, and
wherein a dummy wiring electrically independent of other wirings is formed below the first corner in the multilayer wiring structure.

7. The semiconductor device according to claim 1,
wherein the multilayer wiring structure includes a plurality of low-dielectric-constant insulating films.

8. The semiconductor device according to claim 1,
wherein the protective film is constituted of a stacked film of a silicon nitride film and a silicon oxide film on the silicon nitride film.

9. The semiconductor device according to claim 1,
wherein a thickness of the protective film is 0.4 micrometers to 2.5 micrometers.

10. A semiconductor device comprising:
a semiconductor substrate having a main surface;
a circuit formation region formed on the main surface;
a peripheral region formed on an outer periphery of the circuit formation region in a plan view;
a multilayer wiring structure formed on the main surface and including a plurality of insulating films and a plurality of wiring layers;
a guard ring formed in the peripheral region so as to surround the circuit formation region and so as to penetrate the multilayer wiring structure;
a pad formed on the multilayer wiring structure;
a protective film formed so as to cover the multilayer wiring structure, the guard ring, and the pad; and
a trench formed in the peripheral region so as to surround the guard ring and formed so as to penetrate the protective film and reach an inside of the multilayer wiring structure,
wherein the guard ring includes a first wiring formed on the multilayer wiring structure so as to surround the circuit formation region,
wherein the trench is spaced apart from and adjacent to the first wiring,
wherein the trench has a first corner and a second corner located on opposite sides to each other via the bottom surface of the trench in a direction from the circuit formation region toward the peripheral region,
wherein a distance between the first corner and the first wiring is larger than a distance between the second corner and the first wiring in a plan view, and
wherein a sub-trench is formed at the first corner of the trench.

11. The semiconductor device according to claim 10,
wherein the sub-trench has a slit shape.

12. The semiconductor device according to claim 10,
wherein the sub-trench has a spike shape.

13. The semiconductor device according to claim 10,
wherein the protective film is constituted of a stacked film of a silicon nitride film and a silicon oxide film on the silicon nitride film.

14. The semiconductor device according to claim 10,
wherein a thickness of the protective film is 0.4 micrometers to 2.5 micrometers.

15. A method of manufacturing a semiconductor device, the method comprising:
(a) preparing a semiconductor substrate having a chip region from which a semiconductor chip is acquired and a scribe region surrounding the chip region;
(b) forming a multilayer wiring structure on the semiconductor substrate, a guard ring penetrating the multilayer wiring structure, and a pad on the multilayer wiring structure;
(c) forming a protective film so as to cover the multilayer wiring structure, the guard ring, and the pad;
(d) forming a trench so as to penetrate the protective film and reach an inside of the multilayer wiring structure; and
(e) cutting the semiconductor substrate and the multilayer wiring structure along the scribe region,
wherein the multilayer wiring structure includes a plurality of insulating films and a plurality of wiring layers,
wherein the guard ring is, in the step (b), formed in the chip region so as to surround a circuit formation region of the chip region in a plan view,
wherein the trench is, in the step (d), formed so as to surround the guard ring in the chip region in a plan view,
wherein the guard ring includes a first wiring formed on the multilayer wiring structure so as to surround the circuit formation region,
wherein the trench is spaced apart from and adjacent to the first wiring, and
wherein a bottom surface of the trench is, in the step (d), formed to be inclined so as to be continuously deepened in a direction from the circuit formation region toward the scribe region.

16. The method of manufacturing a semiconductor device according to claim 15,
wherein the step (d) includes:
(d1) forming a photoresist layer on the protective film;
(d2) forming a first opening in the photoresist layer; and
(d3) forming the trench by etching the protective film and the multilayer wiring structure below the first opening using the photoresist layer as an etching mask,
wherein the first opening formed in the step (d2) has a first side surface and a second side surface facing each other, and a part of the photoresist layer remains in the first opening,
wherein a distance between the first side surface and the first wiring is larger than a distance between the second side surface and the first wiring in a plan view, and
wherein a remaining thickness of the photoresist layer gradually decreases in a direction from the second side surface of the first opening toward the first side surface of the first opening at a bottom portion of the first opening formed in the step (d2).

17. The method of manufacturing a semiconductor device according to claim 16,
wherein the photoresist layer formed in the step (d1) has, near the first wiring, a first region whose thickness decreases as a distance from the first wiring increases, and
wherein in the step (d2), the first opening is formed in the first region of the photoresist layer.

18. The method of manufacturing a semiconductor device according to claim 16,
wherein in the step (d2), the first opening and the second opening are formed in the photoresist layer, and
wherein in the step (d3), the trench is formed by etching the protective film and the multilayer wiring structure below the first opening, and a third opening is formed in the protective film by etching the protective film below the second opening, and
wherein a part of the pad is exposed from the third opening of the protective film.

19. The method of manufacturing a semiconductor device according to claim 15,
wherein a shortest distance between the trench and the first wiring is 0.1 micrometers to 1.5 micrometers in a plan view.
